(19) United States
(12) Patent Application Publication
(10) Pub. No.: US 2004/0185385 A1
(43) Pub. Date: Sep. 23, 2004

(54) Method for fabricating a mold

(76) Inventors: Tai-Cherng Yu, Tu-Chen (TW); Charles Leu, Fremont, CA (US); Ga-Lane Chen, Fremont, CA (US)

Correspondence Address: WEI TE CHUNG, FOXCONN INTERNATIONAL, INC., 1650 MEMOREX DRIVE, SANTA CLARA, CA, 95050, US

(21) Appl. No.: 10/806,590

(22) Filed: Mar. 22, 2004

(30) Foreign Application Priority Data
Mar. 21, 2003 (TW) 92106302

(51) Int. Cl. G03F 7/20

(52) U.S. Cl. 430/320; 430/322; 430/323

(57) ABSTRACT

A method for fabricating a mold comprises following steps: providing a base plate (100), forming recesses (200) in the base plate using a series of photo mask processes. These photo mask processes formed a plurality of holes, which cooperatively form recesses of a predetermined shape with high proximity.

### BACKGROUND OF THE INVENTION

1. Field of the Invention

The present invention relates to a mold fabrication method, and particularly to a method for fabricating a mold used for manufacturing a light guide plate.

2. Description of Related Art

In mold fabrication, two methods are widely used; namely, machining and chemical etching. The machining method is relatively easy to perform and costs less, and is therefore commonly used to manufacture low end products that require only low precision. Precision machining can be performed to attain high levels of quality. However, the process is correspondingly costly.

In the chemical etching method, firstly patterns on a base plate are formed. Then the base plate is etched using a chemical solution in order to form the desired structure. In manufacturing a mold for a light guide plate that has round protrusions, anisotropic chemical etching is needed. However, the direction of etching cannot be controlled well in the anisotropic chemical etching method. The fabricated mold often needs repeated modification, which expends additional time and money.

It is desired to provide a method for fabricating a mold which overcomes the above-described problems.

### SUMMARY OF THE INVENTION

An object of the present invention is to provide a mold fabricating method which can readily manufacture a mold with high precision.

To achieve the above object, a mold fabricating method of the present invention comprises the following steps: providing a base plate; and forming a plurality of generally curved recesses through a multi-step photo-mask process.

By repeatedly using precision photo-mask processes, a plurality of holes with various diameters and depths is sequentially formed. The holes cooperatively form recesses having a predetermined shape and high precision.

Other objects, advantages, and novel features of the present invention will become more apparent from the following detailed description when taken in conjunction with the accompanying drawings, in which:

### BRIEF DESCRIPTION OF THE DRAWINGS

FIG. 1 is an isometric view of a base plate for forming a mold according to a first embodiment of the present invention;

FIG. 2 is similar to FIG. 1, but showing the base plate after a first mask procedure has been performed according to the first embodiment of the present invention;

FIG. 3 is a cross-sectional view of part of the base plate of the mold of FIG. 2, taken along line III-III thereof;

FIG. 4 to FIG. 6 are similar to FIG. 3, but respectively show cross-sectional views of the base plate of the mold after second, third and fourth mask procedures have been performed according to the first embodiment of the present invention; and

FIG. 7 is a schematic, cross-sectional view of one recess region of a mold made according to a second embodiment of the present invention.

### DETAILED DESCRIPTION OF THE INVENTION

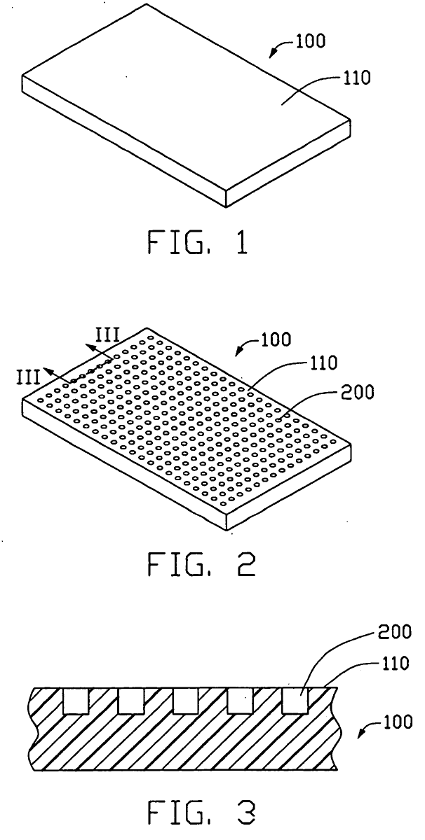

Referring to FIG. 1, a base plate 100 for forming a mold according to the first embodiment of the present invention comprises a working surface 110. The base plate 100 is flat, and can be made of nickel which has a high hardness. Alternatively, the base plate 100 can be made of a nickel alloy.

Several optical lithography processes, i.e. photo-mask procedures, are performed on the base plate 100 to form the mold. As a mature fabricating technology in the semiconductor industry, photo-mask processing is widely used in computer chip manufacturing. One of the advantages of photo-mask processing is high precision, with products like chips usually being very small indeed. The following is a brief introduction of photo-mask processing, which includes making a photo-mask and using the photo-mask to form patterns on a base plate.

In making the photo-mask, firstly a radiation-sensitive material referred to as a photo resist is disposed on an opaque masking layer. The radiation-sensitive material typically comprises an organic polymer. The action of exposing the resist to radiation produces a change in the solubility of exposed regions of the resist film compared with unexposed regions of the resist film. Then in a development step, the difference in solubility is used to form a required pattern in the resist. It should be kept in mind that the solubility of the exposed regions may be either higher or lower than that of the unexposed regions. According to the change brought about by the radiation, the resist is categorized into two types, positive-acting resist and negative-acting resist. For positive resist, the greater the exposure, the thinner the amount of resist remaining. For negative resist, the greater the exposure, the thicker the amount of resist remaining. When either type of resist is employed, by ensuring precise exposure, the remaining resist can form a pattern within specified tolerances, the pattern being etch-proof pattern. This precise exposure is usually realized using either of two kinds of writers, laser writers and e-beam writers. Both writers focus the beams of radiation to a precise point, and both scan the beams in two transverse dimensions on the photo mask opaque masking layer. In the integrated circuit (IC) industry, many writers are made by the most prestigious semiconductor companies because of the need to satisfy the stringent requirements of pattern generation using photo-masks.

Then the opaque masking layer is etched. Parts of the opaque masking layer without resist thereon are etched out, leaving other parts of the opaque masking layer under the patterned resist intact. After that, means such as organic solvents, brush scrubbing, hot acid dips or UV cleaning are used to remove the resist and any other foreign particles, thus providing the desired clean photo-mask.

In using, this mask, often called a photo-mask, with suitable pattern on it, allows radiation passing through it to drop on a base plate, which is covered by a resist film. Then, after a series of similar exposure, etching and cleaning steps, a similar etched pattern like the photo-mask is defined in the base plate. In process of fabricating ICs (integrated circuits), the foregoing procedures are often called a simple photo-mask procedure. Ten or more photo-mask procedures may be used to eventually get an end product, each using a photo-mask with different patterns. And before a new photo mask is used, a step of aligning the new photo-mask with the base plate is needed to allow the exposure taken place in the right place.

Referring to FIG. 2 and FIG. 3, a first photo mask process forms a plurality of cylindric recesses 200 in the base plate 100, each recess has accurate shape of certain depth and diameter. Being fabricated by exposure, which can be seen as projecting the mask to the base plate 100, the recesses 200 form a certain pattern like of the mask on the working surface 110.

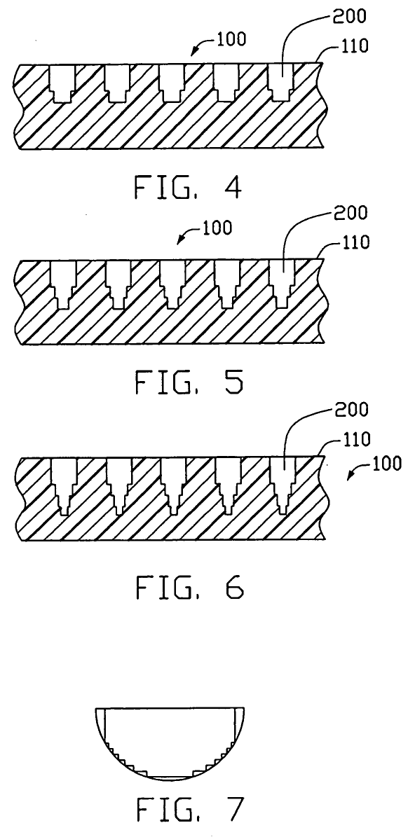

Referring to FIG. 4, FIG. 5 and FIG. 6, cross sectional views of the base plate 100 after a second, a third and a fourth photo mask process are shown. Each process is used to form cylindric recesses, which are in same position of the existed recesses, but are narrower and deeper. The ultimate recesses 200 are the sum of the foregoing four photo mask steps, which are like many birthday cakes placed upside down. To make the cakes looks beautiful, the masks used in these steps should have correct pattern and be aligned to the position of former steps, so each of the cylindric recesses formed by a photo mask steps has same rotating axle as each of the recesses formed by last step.

The mold shown in FIG. 6 can be used to manufacture light guide plate with cake-shaped protrusions on it. In fact, protrusions in shape of half sphere are adopted more often than protrusions like birthday cakes. Referring to FIG. 7, more photo mask processes are performed to turn a birthday cake like recesses into an approximate half sphere shape. With the high precision in photo mask process, recesses can be made of other shapes with high approximation.

With higher precision of etching steps in the photo mask processes, mold for light guide plate comprising protrusions of other shapes can be made. Corresponding to various protrusions wanted, curve-shaped recesses such as semi-elliptical, arch-shaped recesses can be formed in the base plate with high approximation. Beside the recesses having symmetric cross-section, recesses of other irregular shape can be made. And forming such recesses may contain much more photo-mask steps and each of the cylindric recesses formed by a photo mask steps may has different rotating axle as each of the recesses formed by last step. The material of base plate can be nickel alloy.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. A mold fabricating method, comprising:
providing a base plate;
forming recesses in the base plate using a series of photo mask processes.

2. The method as claimed in claim 1, wherein each photo mask process formed recesses.

3. The method as claimed in claim 2, wherein each photo mask process comprises following steps:
covering a resist film on the base plate;
forming a mask;
forming pattern in the resist film by radiation exposure through the mask;
etching the base plate by chemical method to get recesses;
cleaning the remnant resist film and other foreign particles.

4. The method as claimed in claim 3, wherein an aligning step is performed between two photo mask step.

5. The method as claimed in claim 4, wherein the base plate is made of nickel or nickel alloy.

6. The method as claimed in claim 5, wherein the resist film comprises a resist and an organic polymer.

7. The method as claimed in claim 6, wherein the resist film adopts positive acting resist.

8. The method as claimed in claim 6, wherein the resist film adopts negative-acting resist.

9. The method as claimed in claim 1, wherein each photo mask process formed narrower and deeper recesses in the same position of the former photo mask process in the base plate.

10. The method as claimed in claim 9, wherein each photo mask process comprises following steps:
covering a resist film on the base plate;
forming a mask;
forming pattern in the resist film by radiation exposure through the mask;
etching the base plate by chemical method to get recesses;
cleaning the remnant resist film and other foreign particles.

11. The method as claimed in claim 10, wherein an aligning step is performed between two photo mask step.

12. The method as claimed in claim 11, wherein the base plate is made of nickel or nickel alloy.

13. The method as claimed in claim 12, wherein the resist film comprises a resist and an organic polymer.

14. The method as claimed in claim 13, wherein the resist film adopts positive acting resist.

15. The method as claimed in claim 14, wherein the resist film adopts negative-acting resist.
